(19) United States
(12) Patent Application Publication
(10) Pub. No.: US 2024/0309271 A1
(43) Pub. Date: Sep. 19, 2024

(54) POPULATION OF ALLOY NANOCRYSTALS, POPULATION OF CORE-SHELL NANOCRYSTALS, AND USE THEREOF AND SYNTHESIS METHOD THEREFOR

(71) Applicants: ZHEJIANG UNIVERSITY, Hangzhou, Zhejiang (CN); NAJING TECHNOLOGY CORPORATION LIMITED, Hangzhou, Zhejiang (CN)

(72) Inventors: Xiaogang PENG, Hangzhou, Zhejiang (CN); Lin HUANG, Hangzhou, Zhejiang (CN); Jiongzhao LI, Hangzhou, Zhejiang (CN)

(21) Appl. No.: 18/277,785

(22) PCT Filed: Feb. 17, 2022
(86) PCT No.: PCT/CN2022/076583

§ 371 Date: Aug. 18, 2023

(30) Foreign Application Priority Data
Feb. 20, 2021 (CN) 202110193210.7
Mar. 12, 2021 (CN) 202110271176.0

(51) Int. Cl. C09K 11/88; C30B 25/02

(52) U.S. Cl. CPC C09K 11/883; C30B 25/02

(57) ABSTRACT

The present disclosure provides a population of alloy nanocrystals, a population of core-shell nanocrystals, and a synthesis method therefor, a composition comprising same, and an electronic device. The population of alloy nanocrystals comprises a plurality of alloy nanocrystals, wherein each of the alloy nanocrystals comprises a first group II element, a second group II element, and a first group VI element, the population of alloy nanocrystals has a Raman peak with a full-width-at-half-maximum of less than or equal to 15 cm⁻¹, and the alloy nanocrystals have an average size greater than a diameter of an exciton of a corresponding bulk alloy compound. The population of alloy nanocrystals has an excellent narrow full-width-at-half-maximum.

### CROSS-REFERENCE TO RELATED APPLICATIONS

This application is based on the Chinese Patent application No.CN202110193210.7 (filed on Feb. 20, 2021) and the Chinese Patent application No.CN202110271176.0 (filed on Mar. 12, 2021). The contents of CN202110193210.7 and CN202110271176.0 are all hereby incorporated by reference.

### TECHNICAL FIELD

The present disclosure relates to the field of semiconductor nanocrystals, and in particular to a population of alloy nanocrystals, a population of core-shell nanocrystals, and a synthesis method therefor, a composition comprising same, and an electronic device.

### BACKGROUND

The synthesis technology of semiconductor nanocrystals, especially group II-VI nanocrystals, has developed remarkably in the past decade. The fluorescence peak width of the nanocrystals is usually measured by full-width-at-half-maximum (FWHM). Factors affecting the FWHM include intrinsic (homogeneous) and inhomogeneous peak widths. The fluorescence peak width of a single nanocrystal approximates the intrinsic fluorescence FWHM of a specific nanocrystal; a population of nanocrystals with different sizes have different emission wavelengths, resulting in inhomogeneous broadening of fluorescence peak positions.

In specific applications, the FWHM of the nanocrystals in the prior art is still relatively wide. For example, in a single CdSenanocrystal, at present, an FWHM of 22 nm can be achieved for a blue CdSenanocrystal, 20 nm for a green CdSenanocrystal, and 19 nm for a red CdSenanocrystal. The FWHM of the common CdZnSe alloy nanocrystals is 20-40 nm. One method to reduce the FWHM is to epitaxially grow wide-bandgap shell layers such that the photon-generated excitons are far from the inorganic-organic interface, e.g., coating CdSe with CdS shells. Another method is to obtain nanocrystals with perfect surfaces, such as CdSenanosheets which are, however, not stable enough and accompanied by broadening of the fluorescence FWHM during the further coating process.

### SUMMARY

The present disclosure aims to provide a population of alloy nanocrystals and a population of core-shell nanocrystals having a narrowed fluorescence FWHM, and a synthesis method therefor, a composition, and an electronic device.

According to the first aspect of present disclosure, a population of alloy nanocrystals is provided, the population of alloy nanocrystals includes a plurality of alloy nanocrystals, each of the alloy nanocrystals includes a first group II element, a second group II element, and a first group VI element, the population of alloy nanocrystals has a Raman peak with a full-width-at-half-maximum of less than or equal to 15 cm⁻¹, and the alloy nanocrystals have an average size greater than a Bohr diameter of an exciton of a corresponding bulk alloy compound.

Optionally, the population of alloy nanocrystals has a fluorescence full-width-at-half-maximum of less than or equal to 18 nm, and the alloy nanocrystals have a zinc-blende structure.

According to the second aspect of present disclosure, a population of core-shell nanocrystals is provided, the population of core-shell nanocrystals includes at least one core-shell nanocrystal, the core-shell nanocrystal includes one alloy nanocrystalin the any one of the above population of alloy nanocrystals and further includes a II-VI shell layer that coats the alloy nanocrystal.

According to the third aspect of present disclosure, a composition is provided, the composition includes any one of the population of alloy nanocrystals or any one of the population of core-shell nanocrystals.

According to the fourth aspect of present disclosure, an electronic device is provided, the device includes any one of the population of alloy nanocrystals or any one of the population of core-shell nanocrystals.

According to the fifth aspect of present disclosure, a synthesis method for a population of alloy nanocrystals is provided, the synthesis method includes: S1, preparing a dispersion containing first II-VI nanocrystal cores; S2, preparing a mixture containing a second group II element precursor, a second group VI element precursor, a free ligand, and a solvent in a reaction container, heating the mixture to a first temperature, adding the dispersion into the reaction container, and epitaxially growing a plurality of first II-VI/second II-VI core-shell nanocrystals, a second group II element in the second group II element precursor is different from a first group II element in the first II-VI nanocrystal cores, and an average size of the first II-VI/second II-VI core-shell nanocrystals is controlled to be greater than a Bohr diameter of an exciton of a group II-VI compound containing the same corresponding elements; and S3, adding metal ions as a catalyst into the reaction container and conducting, at a second temperature, a conversion of the first II-VI/second II-VI core-shell nanocrystals into alloy nanocrystals to obtain a population of alloy nanocrystals including a plurality of the alloy nanocrystals.

According to the sixth aspect of present disclosure, a synthesis method for a population of core-shell nanocrystals is provided, the synthesis method includes: synthesizing a population of alloy nanocrystals including a plurality of alloy nanocrystals by any one of the synthesis method above, the synthesis method further includes: S4, epitaxially growing a first shell layer on a surface of the alloy nanocrystal and epitaxially growing a second shell layer on a surface of the first shell layer.

The population of alloy nanocrystals and the population of core-shell nanocrystals described above have excellent narrow FWHM. The synthesis method described above can achieve a population of nanocrystals with a narrow FWHM.

### BRIEF DESCRIPTION OF THE DRAWINGS

The accompanying drawings constituting a part of the present disclosure are intended to provide further understanding of the present disclosure. The exemplary embodiments of the present disclosure and illustrations thereof are used to explain the present disclosure and do not constitute an undue limitation to the present disclosure. In the accompanying drawings:

FIG. 1 shows a diagram of changes in transmission electron microscopy(TEM) of a population of nanocrystals during the synthesis according to one embodiment of the present disclosure (information on the average size is shown in the lower left corner).

FIG. 2 shows a diagram of changes in TEM of a population of nanocrystals during the synthesis according to another embodiment of the present disclosure (information on the average size is shown in the lower left corner).

FIG. 3 shows a schematic diagram of changes during the synthesis of a population of nanocrystals according to one method embodiment of the present disclosure.

FIG. 4 shows plots of changes in performance characteristics during the synthesis of a population of nanocrystals according to one method embodiment of the present disclosure, where a is a plot showing changes in ultraviolet-visible (UV-Vis) absorption spectrum over time, b is a plot showing changes in photoluminescence (PL) fluorescence spectrum over time, and c is a plot showing changes in PL fluorescence peak position and FWHM over time.

FIG. 5 shows plots of changes in performance characteristics during the synthesis of a population of nanocrystals according to another method embodiment of the present disclosure, where a is a plot showing changes in UV-Vis absorption spectrum over time, b is a plot showing changes in PL fluorescence spectrum over time, and c is a plot showing changes in PL fluorescence peak position and FWHM over time.

FIG. 6 shows plots of changes in characteristics of a population of nanocrystals after multiple times of hydrochloric acid (HCl) etching according to one embodiment of the present disclosure, where a is a plot showing changes in UV-Vis absorption spectrum over the amount of hydrochloric acid addition, b is a plot showing changes in the average size of the population of nanocrystals over the amount of hydrochloric acid addition, and c is a plot showing the relationship between the molar ratio of Cd:Zn and the amount of hydrochloric acid addition.

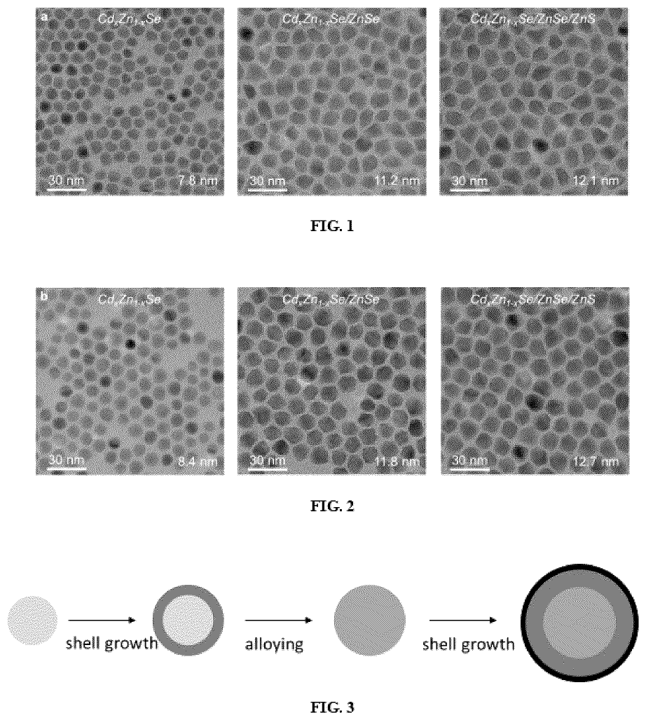

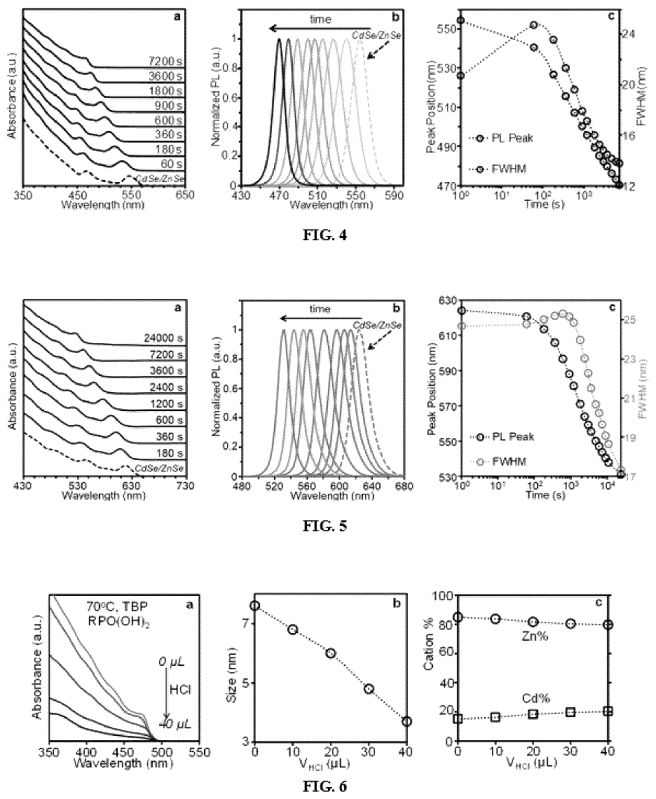

In FIG. 7, the upper panel shows a plot of changes in Raman spectrum during the synthesis of a population of nanocrystals according to one embodiment of the present disclosure, and the lower panel shows Raman spectra of the population of CdSenanocrystals (first exciton absorption peak=550 nm) and the population of corresponding alloy nanocrystals.

In FIG. 8, the upper panel shows a plot of changes in Raman spectrum during the synthesis of a population of nanocrystals according to another embodiment of the present disclosure, and the lower panel shows Raman spectra of the population of CdSenanocrystals (first exciton absorption peak=630 nm) and the population of corresponding alloy nanocrystals.

In FIG. 9, the upper panel shows fluorescence spectra of a population of alloy nanocrystals and its population of coated core-shell nanocrystals according to one embodiment of the present disclosure, and the lower panel shows a fluorescence spectrum of a single nanocrystal in the corresponding population of nanocrystals.

In FIG. 10, the upper panel shows fluorescence spectra of a population of alloy nanocrystals and its population of coated core-shell nanocrystals according to another embodiment of the present disclosure, and the lower panel shows a fluorescence spectrum of a single nanocrystal in the corresponding population of nanocrystals.

FIG. 11 shows X-ray diffraction (XRD) spectra of the powders of the resulting populations of nanocrystals at various stages according to one embodiment of the present disclosure, with the nanocrystals at the various stages being CdSe, CdSe/ZnSe, CdₓZn₁₋ₓ, Se, and CdₓZn₁₋ₓSe/ZnSe/ZnS, respectively.

“Alloy/shell” in the figures refers to CdₓZn₁₋ₓSe/ZnSe/ZnS core-shell nanocrystals with alloy nanocrystals as cores.

### DETAILED DESCRIPTION

It should be noted that the following detailed descriptions are all exemplary and are intended to provide further explanation of the present disclosure. Unless otherwise stated, all technical and scientific terms used herein have the same meaning as commonly understood by those of ordinary skill in the art to which the present disclosure belongs.

It should be noted that the terms “first”, “second”, and so on in the specification and claims of the present disclosure are intended to distinguish between similar objects but do not necessarily describe a specific order or sequence. It should be understood that the data termed in such a way are interchangeable under appropriate circumstances so that the embodiments of the present disclosure described herein can be implemented in other orders than the order illustrated or described herein. Moreover, the terms “comprise” and “have” and any variations thereof are intended to cover the non-exclusive inclusion. For example, a process, method, system, product or device comprising a series of steps or units is not necessarily limited to the explicitly listed steps or units, but may comprise other steps or units that are not explicitly listed or are inherent in the process, method, product or device. Exemplary embodiments of nanocrystals provided according to the present disclosure will be described in more detail below. These exemplary embodiments may, however, be implemented in many different forms and should not be construed as being limited to the embodiments set forth herein. It should be understood that these embodiments are provided to make the present disclosure thorough and complete, and to fully convey the concept manifested in these exemplary embodiments to those of ordinary skill in the art.

As used in the present disclosure, “group” refers to a group of the periodic table of elements. The alloy nanocrystals or core-shell nanocrystals used in the present disclosure are all semiconductor nanocrystals. The “average size” is a statistical result in the population of nanocrystals, wherein the average size is a diameter for spherical nanocrystals and is a diameter calculated from a two-dimensional area (e.g., assuming that the two-dimensional area forms a circle) of a TEM image for non-spherical nanocrystals. The FWHM of the Raman peak and the FWHM of the fluorescence emission are both peak widths at half the peak height.

As described in the background, the nanocrystals in the prior art have relatively low fluorescence FWHM performance. According to a first aspect of the present disclosure, provided is a population of alloy nanocrystals, comprising a plurality of alloy nanocrystals, wherein each of the alloy nanocrystals comprises a first group II element, a second group II element, and a first group VI element, the population of alloy nanocrystals has a Raman peak with an FWHM of less than or equal to 15 cm⁻¹, and the alloy nanocrystals have an average size greater than a Bohr diameter of an exciton of a corresponding bulk alloy compound. Alloy nanocrystals with such a structure have an extremely narrow FWHM, so that a population of alloy nanocrystals composed of the alloy nanocrystals also has a narrow FWHM. The first group II element is different from the second group II element, as understood from the meaning of alloy. It can be considered that the narrower the FWHM of the Raman peak is, the more uniform the distribution of component elements in the alloy nanocrystals is, and if the elements are uniformly distributed, the FWHM of the alloy nanocrystals is narrower. The average size of the alloy nanocrystals is greater than the Bohr diameter of the exciton of the corresponding bulk alloy compound, so that the surface effect of the excitons can be reduced and the FWHM of the alloy nanocrystals is also narrowed, both of which play a role in narrowing the FWHM. If the alloy nanocrystals are CdZnSe, the “corresponding bulk alloy compound” is a bulk CdZnSe compound.

In some embodiments, each of the alloy nanocrystals may further comprise other elements, such as a second group VI element, which is of a different type than the first group VI element. In some embodiments, each of the alloy nanocrystals may further comprise a third group VI element.

In some embodiments, the population of alloy nanocrystals described above has a fluorescence FWHM of less than or equal to 17.5 nm, or less than or equal to 17 nm, or less than or equal to 16.5 nm, or less than or equal to 16 nm, or less than or equal to 15.5 nm, or less than or equal to 15 nm, or less than or equal to 14.5 nm, or less than or equal to 14 nm, or less than or equal to 13.5 nm, or less than or equal to 13 nm, or less than or equal to 12.5 nm, or less than or equal to 12 nm.

In some embodiments, the population of alloy nanocrystals described above has a fluorescence FWHM of greater than or equal to 5 nm, or greater than or equal to 6 nm.

In some embodiments, the population of alloy nanocrystals described above has a Raman peak with an FWHM of greater than or equal to 10 cm⁻¹.

In some embodiments, the population of alloy nanocrystals described above has a fluorescence emission peak wavelength being green-emitting, with a Raman peak position of 239 cm⁻¹. In some embodiments, the population of alloy nanocrystals described above has a fluorescence emission peak wavelength being blue-emitting, with a Raman peak position of 248 cm⁻¹.

In some embodiments, the population of alloy nanocrystals has a fluorescence FWHM of less than or equal to 18 nm, wherein the alloy nanocrystals have a zinc-blende structure.

In some embodiments, the alloy nanocrystals described above are CdZnSe.

In some embodiments, the CdZnSe alloy nanocrystals have a cadmium-to-zinc molar ratio of 7:93 to 33:67. The maximum photoluminescence emission wavelength of the alloy nanocrystals can be adjusted by adjusting the content of cadmium and zinc. The molar ratio described above can be obtained by theoretical calculation of the feeding amounts in the preparation of the alloy nanocrystals, and can also be obtained by actual measurement means such as atomic absorption spectroscopy (AAS). Considering that the ratio has a certain measurement error or theoretical deviation error, it is contemplated that a range of ratios close to (±5%, or 10%, or ±15%, or ±20%) the ratio are within the protection scope of this patent.

In some embodiments, the population of alloy nanocrystals has a quantum efficiency of greater than or equal to 50%. In some embodiments, the population of alloy nanocrystals has a quantum efficiency of greater than or equal to 55%, or greater than or equal to 60%, or greater than or equal to 65%, or greater than or equal to 70%. In some embodiments, the population of alloy nanocrystals has a quantum efficiency of 50%-70%.

In some embodiments, the population of alloy nanocrystals has a photoluminescence emission wavelength of 450-540 nm.

In some embodiments, the population of alloy nanocrystals has a photoluminescence emission wavelength of 525-535 nm and a fluorescence FWHM of 17-18 nm. In some embodiments, the population of alloy nanocrystals described above has a band gap of 2.32-2.36 eV.

In some embodiments, at least one alloy nanocrystal of the green-emitting population of alloy nanocrystals has a fluorescence FWHM of 9-10 nm.

In some embodiments, the population of alloy nanocrystals has a photoluminescence emission wavelength of 455-475 nm and a fluorescence FWHM of 12-14 nm. In some embodiments, the population of alloy nanocrystals described above has a bandgap of 2.61-2.72 eV.

In some embodiments, at least one alloy nanocrystal of the blue-emitting population of alloy nanocrystals has a fluorescence FWHM of 5-6 nm.

In some embodiments, the alloy nanocrystals have an average size of less than 20 nm. In some embodiments, the alloy nanocrystals have an average size of less than or equal to 15 nm, or less than or equal to 10 nm, preferably 7-9 nm.

In some embodiments, the alloy nanocrystals are free of light emission by copper element.

In some embodiments, copper element is involved in the synthesis of the population of alloy nanocrystals, but the doping amount of copper element in the alloy nanocrystals is preferably very low or 0, so as to achieve the preferred situation of almost no light emission by copper element.

In some embodiments, a ligand of the alloy nanocrystals comprises trialkylphosphine and carboxylate. The alkyl groups of the trialkylphosphine may be each independently selected from C₂-C₁₀ alkyl carbon chains, and the carboxyl group of the carboxylate may be a carboxyl group with a carbon chain length of 8-22.

In some embodiments, the population of alloy nanocrystals has a Raman peak with an FWHM of greater than or equal to 10 cm⁻¹.

According to a second aspect of the present disclosure, provided is a population of core-shell nanocrystals, wherein the population of core-shell nanocrystals comprises at least one core-shell nanocrystal, the core-shell nanocrystal comprising one alloy nanocrystal in any one of the populations of alloy nanocrystals described above and further comprising a II-VI shell layer that coats the alloy nanocrystal. The epitaxial II-VI shell layer further narrows the FWHM of the population of nanocrystals.

In some embodiments, the II-VI shell layer is ZnS, ZnSe, or a combination thereof.

In some embodiments, the II-VI shell layer of the core-shell nanocrystal comprises a ZnSe shell layer and a ZnS shell layer, the ZnSe shell layer being equivalent to 5-6 monolayers and the ZnS shell layer being equivalent to 1-2 monolayers. The number of monolayers described above is used to describe the thickness of the shell layer. In this way, a better narrow FWHM can be obtained.

In some embodiments, the II-VI shell layer of the core-shell nanocrystal is a ZnSe shell layer, the ZnSe shell layer having a thickness of 5-20 monolayers.

In some embodiments, the population of core-shell nanocrystals has a photoluminescence emission wavelength of 455-475 nm and a fluorescence FWHM of less than or equal to 11 nm, or less than or equal to 10.5 nm, or less than or equal to 10.2 nm. In some embodiments, at least one core-shell nanocrystal in the population of core-shell nanocrystals has a fluorescence FWHM of less than or equal to 6 nm, or less than or equal to 5.5 nm, or less than or equal to 5.2 nm.

In some embodiments, the population of core-shell nanocrystals has a photoluminescence emission wavelength of 520-535 nm and a fluorescence FWHM of less than or equal to 17 nm, or less than or equal to 16.5 nm, or less than or equal to 16.3 nm. In some embodiments, at least one core-shell nanocrystal of the population of core-shell nanocrystals has a fluorescence FWHM of less than or equal to 10 nm (i.e., the level of a single nanocrystal), or less than or equal to 9.7 nm.

In some embodiments, the population of core-shell nanocrystals has a quantum efficiency of greater than or equal to 60%. In some embodiments, the population of alloy nanocrystals has a quantum efficiency of greater than or equal to 65%, or greater than or equal to 70%, or greater than or equal to 75%, or greater than or equal to 80%. In some embodiments, the population of alloy nanocrystals has a quantum efficiency of 60%-80%.

In some embodiments, the population of core-shell nanocrystals has a Raman peak with a Raman shift of 239-248 cm⁻¹.

In some embodiments, the population of core-shell nanocrystals has a Raman peak with an FWHM of less than or equal to 12 cm⁻¹, or less than or equal to 10 cm⁻¹.

In some embodiments, the ligands of the alloy nanocrystals and the core-shell nanocrystals are independently selected from RCOOH, RNH₂, R₂NH, R₃N, RSH, RH₂PO, R₂HPO, R₃PO, RH₂P, R₂HP, R₃P, ROH, RCOOR′, RPO(OH)₂, RHPOOH, R₂POOH, polymer organic ligands, and combinations thereof, wherein R and R′ are the same or different, and are each independently a substituted or unsubstituted C₁-C₄₀(e.g., C₃-C₃₀ or C₆-C₂₄) aliphatic hydrocarbon(alkyl, alkenyl, or alkynyl)group or a substituted or unsubstituted C₆-C₄₀ aromatic hydrocarbon group, or a combination thereof.

In some embodiments, the ligands of the alloy nanocrystals and the core-shell nanocrystals independently do not include amine ligands, particularly fatty amine ligands.

In some embodiments, the ligands of the alloy nanocrystals and the core-shell nanocrystals are independently dispersible in C₆-C₄₀ aliphatic hydrocarbons, C₆-C₄₀ aromatic hydrocarbons, or combinations thereof.

The alloy nanocrystals and the core-shell nanocrystals may be in various shapes. In some embodiments, the alloy and populations of core-shell nanocrystals comprise a plurality of spherical nanocrystals, wherein the plurality of nanocrystals may have an average roundness of greater than or equal to about 0.70. The nanocrystals may have an average roundness of greater than or equal to about 0.75. The nanocrystals may have an average roundness of greater than or equal to about 0.80. The word “roundness” may refer to a definition as provided in The ImageJ User Guide (v 1.46r) and may be defined as follows: 4×{[area]/(π×[major axis]²)}. The above definition may correspond to the reciprocal of the aspect ratio. The aspect ratio may be the ratio of the major axis to the minor axis. The “area” may be the area of a two-dimensional image of a given particle, and the major axis may refer to the major axis of the best-fit elliptical shape of the given image. The roundness may be such that it may reflect the ratio between the inscribed circle and the circumscribed circle for a given object.

In some embodiments, the relative standard deviation (RSD) of the size of the nanocrystals in the population of alloy nanocrystals or population of core-shell nanocrystals described above is less than or equal to 15%, or less than or equal to 10%, or less than or equal to 8%, or less than or equal to 6%.

In some embodiments, the nanocrystals of the population of alloy nanocrystals or population of core-shell nanocrystals described above have doped elements, wherein the doped elements do not participate in light emission, but may have other properties, such as improving the stability of the population of nanocrystals.

According to a third aspect of the present disclosure, provided is a composition, comprising any one of the populations of alloy nanocrystals described above or any one of the populations of core-shell nanocrystals described above.

In some embodiments, the composition further comprises a dispersant (e.g., a binder monomer or polymer), a polymerizable (photopolymerizable) monomer having a carbon-carbon double bond (e.g., at least one carbon-carbon double bond), an initiator (photoinitiator), or a combination thereof, wherein the binder monomer or polymer may comprise a carboxylic acid group. The composition may further comprise an organic solvent, a liquid carrier (vehicle), or a combination thereof.

According to a fourth aspect of the present disclosure, provided is an electronic device, comprising any one of the populations of alloy nanocrystals described above or any one of the populations of core-shell nanocrystals described above.

In some embodiments, the electronic device comprises the population of alloy nanocrystals or the population of core-shell nanocrystals described above. The device may include a display device, a light-emitting diode (LED), an organic light-emitting diode (OLED), a quantum dot LED, a sensor, a solar cell, an image sensor, and a liquid crystal display (LCD), but is not limited thereto.

In one embodiment, the electronic device may be an LCD device, a photoluminescent element (e.g., a lighting device, such as a quantum dot sheet, a quantum dot plate, or a backlight unit for a liquid crystal display (LCD)), or an electroluminescent device (e.g., a QD LED).

In one embodiment, the electronic device may comprise a quantum dot sheet and the nanocrystal may be included in the quantum dot sheet (e.g., in the form of a nanocrystal-polymer complex).

In one embodiment, the electronic device may be an electroluminescent device. The electronic device may comprise an anode and a cathode facing each other, as well as a nanocrystal emission layer provided between the anode and the cathode and comprising a plurality of nanocrystals.

According to a fifth aspect of the present disclosure, provided is a synthesis method for a population of alloy nanocrystals, comprising:
S1, preparing a dispersion containing first II-VI nanocrystal cores;
S2, preparing a mixture containing a second group II element precursor, a second group VI element precursor, a free ligand, and a solvent in a reaction container, heating the mixture to a certain temperature, adding the dispersion into the reaction container, and epitaxially growing a plurality of first II-VI/second II-VI core-shell nanocrystals, wherein a second group II element in the second group II element precursor is different from a first group II element in the first II-VI nanocrystal cores, and an average size of the first II-VI/second II-VI core-shell nanocrystals is controlled to be greater than a Bohr diameter of an exciton of a group II-VI compound containing the same corresponding elements; and
S3, adding metal ions as a catalyst into the reaction container and conducting, at a certain temperature, a conversion of the first II-VI/second II-VI core-shell nanocrystals into alloy nanocrystals to obtain a population of alloy nanocrystals comprising a plurality of the alloy nanocrystals.

In order to reduce the PL FWHM of the nanocrystals, the synthesis method comprises the processes of nucleation of the first II-VI nanocrystals, epitaxial growth of the monodisperse first II-VI/second II-VI core-shell nanocrystals, and alloying. By controlling the relationship between the average size of the first II-VI/second II-VI core-shell nanocrystals and the size of the Bohr diameter of the exciton of the group II-VI compound and by catalyzing with the metal ions, a more uniform alloying in the nanocrystals is achieved. The “group II-VI compound containing the same corresponding elements” described above refers to a bulk compound with the same chemical composition, for example, the CdSe/ZnSenanocrystal corresponds to a bulk CdZnSe compound. The catalytic effect of the metal ions means that the metal ions hardly remain in the lattices of the nanocrystals, and the metal ions enter and exit the nanocrystals very quickly during the synthesis of the nanocrystals.

In the first II-VI/second II-VI core-shell nanocrystals, the core-shell interface may be partially alloyed, which is specifically manifested in a blue shift in the fluorescence peak position of the nanocrystals during the coating process. After completion of the alloying in S3, the average size of the first II-VI/second II-VI core-shell nanocrystals is close to or equal to the average size of the alloy nanocrystals, which is almost constant.

In some embodiments, the type of the group VI element in the second group VI element precursor described above is different from that of the group VI element in the first II-VI nanocrystal cores described above.

In some embodiments, the ionic radius of the metal ions as the catalyst is small enough to enter and exit the first II-VI/second II-VI core-shell nanocrystals.

The “group II” described above refers to group IIA and group IIB, and examples of group II metals may include Cd, Zn, Hg, and Mg. The “group VI” described above refers to group VIA and may include sulfur, selenium, and tellurium.

In some embodiments, a zinc precursor may include Zn powder, ZnO, an alkylated zinc compound (e.g., C₂-C₃₀ alkyl (e.g., dialkyl) zinc, such as dimethyl zinc and diethyl zinc), zinc alkoxide (e.g., zinc ethoxide), zinc carboxylate (e.g., zinc acetate or aliphatic zinc carboxylate, such as long-chain aliphatic zinc carboxylate (e.g., zinc oleate)), zinc nitrate, zinc perchlorate, zinc sulfate, zinc acetylacetonate, zinc halide (e.g., zinc chloride), zinc cyanide, zinc hydroxide, zinc carbonate, zinc peroxide, and a combination thereof.

Examples of the zinc precursor may include dimethyl zinc, diethyl zinc, zinc acetate, zinc acetylacetonate, zinc iodide, zinc bromide, zinc chloride, zinc fluoride, zinc carbonate, zinc cyanide, zinc nitrate, zinc oxide, zinc peroxide, zinc perchlorate, zinc sulfate, and a combination thereof.

In some embodiments, a selenium precursor may include selenium-trioctylphosphine (Se-TOP), selenium-tributylphosphine (Se-TBP), selenium-triphenylphosphine (Se-TPP), selenium-diphenylphosphine (Se-DPP), and a combination thereof, but is not limited thereto.

In some embodiments, a tellurium precursor may include tellurium-trioctylphosphine (Te-TOP), tellurium-tributylphosphine (Te-TBP), tellurium-triphenylphosphine (Te-TPP), tellurium-diphenylphosphine (Te-DPP), and a combination thereof, but is not limited thereto.

In some embodiments, a sulfur precursor may include hexanethiol, octanethiol, decanethiol, dodecanethiol, hexadecanethiol, mercaptopropylsilane, sulfur-trioctylphosphine (S-TOP), sulfur-tributylphosphine (S-TBP), sulfur-triphenylphosphine (S-TPP), sulfur-trioctylamine (S-TOA), sulfur-octadecene (S-ODE), bis(trimethylsilyl) sulfide, ammonium sulfide, sodium sulfide, and a combination thereof.

In some embodiments, the solvent is selected from a non-coordinating solvent, which may be specifically ODE.

In some embodiments, the free ligand is selected from RCOOH, RNH₂, R₂NH, R₃N, RSH, RH₂PO, R₂HPO, R₃PO, RH₂P, R₂HP, R₃P, ROH, RCOOR′, RPO(OH)₂, RHPOOH, R₂POOH, polymer organic ligands, and combinations thereof, wherein R and R′ are the same or different, and are each independently a substituted or unsubstituted C₁-C₄₀ (e.g., C₃-C₃₀ or C₆-C₂₄) aliphatic hydrocarbon(alkyl, alkenyl, or alkynyl)group or a substituted or unsubstituted C₆-C₄₀ aromatic hydrocarbon group, or a combination thereof.

In some embodiments, the reaction temperature for forming the first II-VI nanocrystals/second II-VI core-shell nanocrystals (first temperature) may be greater than or equal to about 250° C., greater than or equal to about 260° C., greater than or equal to about 270° C., greater than or equal to about 280° C., greater than or equal to about 290° C., or greater than or equal to about 300° C. The reaction temperature for forming the nanocrystal cores may be less than or equal to about 350° C., e.g., less than or equal to about 340° C., less than or equal to about 330° C., less than or equal to about 320° C., or less than or equal to about 310° C.

In some embodiments, the zinc precursor may be reacted with the selenium precursor to form a first shell layer comprising zinc and selenium, and then reacted with the sulfur precursor to form a second shell layer comprising zinc and sulfur.

In some embodiments, the II-VI shell layer comprises a ZnSe shell layer and a ZnS shell layer, wherein the ZnSe shell layer has a thickness of 5-6 monolayers, and the ZnS shell layer has a thickness of 1-2 monolayers. In some embodiments, the first shell layer is a ZnSe shell layer, and the second shell layer is a ZnS shell layer.

In some embodiments, the synthesis method further comprises: S4, epitaxially growing a first shell layer on the surface of the alloy nanocrystal. For example, the formation of the shell layer of the alloy nanocrystal may comprise reacting a zinc precursor with a selenium precursor, or may comprise reacting a zinc precursor with a sulfur precursor.

In some embodiments, the reaction temperature for forming the outermost II-VI shell layer of the nanocrystal (second temperature) may be appropriately selected within any suitable range of greater than or equal to about 200° C., e.g., greater than or equal to about 210° C., greater than or equal to about 220° C., greater than or equal to about 230° C., greater than or equal to about 240° C., greater than or equal to about 250° C., greater than or equal to about 260° C., greater than or equal to about 270° C., greater than or equal to about 280° C., or greater than or equal to about 290° C., and less than or equal to about 340° C., e.g., less than or equal to about 325° C.

In some embodiments, the second group II element precursor and the second group VI element precursor are in a molar ratio of 1:1. It should be noted that the molar ratio herein is based on the ratio of the second group II element to the second group VI element.

In some embodiments, the second group VI element precursor is added in batches.

In some embodiments, the reaction time for each of S2 and S3 may be comprehensively determined based on the reaction rate, the size of the nanocrystals of interest, the emission wavelength, and other factors, and may be 30 min, or 60 min, or 120 min, or 180 min.

In some embodiments, the first II-VI/second II-VI core-shell nanocrystals have an average size of 7-9 nm.

In some embodiments, the free ligand comprises a fatty acid.

In some embodiments, the fatty acid is selected from C₂-C₂₂ fatty acids, preferably C₈-C₂₂ fatty acids.

In some embodiments, the carbon chain length of the fatty acid is different from that of the group II precursor, such that an entropic ligand is formed, increasing the solubility of larger-size nanocrystals. For the definition of the entropic ligand, reference can be made to the published literature of the inventors.

In some embodiments, the fatty acid and the second group II element precursor (using the second group II element as the calculation basis for the amount of substance) are in a molar ratio of less than or equal to 4:1. The phenomenon of self-nucleation is reduced.

In some embodiments, the shell layers in the first II-VI/second II-VI core-shell nanocrystals have a thickness of greater than or equal to 4 monolayers, or greater than or equal to 2.5 nm.

The synthesis method described above can be used for the alloying of thick-shell nanocrystals, whereas in the prior art, it is necessary to strictly control the thickness of the shell layers within a thinner range to achieve (uniform) alloying.

In some embodiments, the shell layers in the first II-VI/second II-VI core-shell nanocrystals have a thickness equal to an average size of the II-II-VI nanocrystals minus an average size of the first II-VI nanocrystal cores, the average size of the II-II-VI nanocrystals being a predetermined size of interest. The predetermined size of interest is determined based on actual requirements or determined through exploratory experiments.

In some embodiments, the amount of the reaction precursor in S2 described above is sufficient to obtain alloy nanocrystals of a predetermined size of interest.

In some embodiments, the population of alloy nanocrystals has a fluorescence FWHM of less than or equal to 18 nm. In some embodiments, the population of alloy nanocrystals described above has a fluorescence FWHM of less than or equal to 17.5 nm, or less than or equal to 17 nm, or less than or equal to 16.5 nm, or less than or equal to 16 nm, or less than or equal to 15.5 nm, or less than or equal to 15 nm, or less than or equal to 14.5 nm, or less than or equal to 14 nm, or less than or equal to 13.5 nm, or less than or equal to 13 nm, or less than or equal to 12.5 nm, or less than or equal to 12 nm.

In some embodiments, the metal ions are cupric ions, which have a better catalytic effect.

In some embodiments, it is preferred that the reaction temperature (i.e., the second temperature) for the conversion of the alloying is 300-330° C., a temperature range that has a higher reaction efficiency. The temperature may be constant or may vary within a range, for example, being maintained at 300° C. for a first time period of reaction and then being maintained at 330° C. for a second time period of reaction. The conversion of the alloying process can also be conducted at a reaction temperature of lower than 300° C., but the reaction rate is low.

In some embodiments, the metal ions as the catalyst and the first II-VI/second II-VI core-shell nanocrystals are in a molar concentration ratio of 1:1 to 1:10, and the lower concentration of the metal ions may exert a catalytic effect (reducing the doping). In some embodiments, the metal ions and the first II-VI/second II-VI core-shell nanocrystals are in a molar concentration ratio of 1:1, thereby minimizing the dopant light emission by copper element. If the metal ions have a relatively high molar concentration, they may remain in the nanocrystals and cause dopant light emission, thereby interfering with the light emission purity of the nanocrystals. Of course, the nanocrystals may also have dual light-emitting properties, if desired.

In some embodiments, the second group II element precursor comprises a fatty acid salt of a second group II element, and no fatty amine is present in the reactions of both S2 and S3, avoiding aminolysis of the fatty acid salt of the group II element at high temperatures.

In some embodiments, the first II-VI nanocrystal cores are CdSe, the first II-VI/second II-VI core-shell nanocrystals are CdSe/ZnSe, and the alloy nanocrystals are CdZnSe.

In some embodiments, the first II-VI nanocrystal cores have a zinc-blende structure, thereby ensuring that the final product also has a zinc-blende structure.

In some embodiments, in Si described above, a product system of first II-VI nanocrystal cores is first synthesized, then the product system is subjected to separation and purification to obtain first II-VI nanocrystal cores, and the first II-VI nanocrystal cores are mixed with a dispersant and uniformly dispersed to obtain a dispersion containing the first II-VI nanocrystal cores. For the method for preparing the first II-VI nanocrystal cores, reference can be made to the prior art.

In a sixth aspect of the present disclosure, provided is a synthesis method for a population of core-shell nanocrystals, comprising synthesizing a population of alloy nanocrystals by any one of the synthesis methods described above, wherein the synthesis method further comprises: S4, epitaxially growing a first shell layer on the surface of the alloy nanocrystal described above and epitaxially growing a second shell layer on the surface of the first shell layer described above, thereby further protecting the alloy nanocrystal while reducing the fluorescence FWHM. FIG. 3 is a schematic diagram of a simplified process of the synthesis method.

If “nanocrystal” is used instead of “population of nanocrystals” in the expression herein, it should be determined based on the context whether a population of nanocrystals is being described. The population of alloy nanocrystals, the population of core-shell nanocrystals, and the synthesis method therefor described above of the present disclosure will be further illustrated with reference to the following specific examples.

The Chemicals Used were as Follows:

1-Octadecene (ODE, 90%), cadmium oxide (CdO, 99.998%), zinc stearate (Zn(St)₂, impurity ZnO 12.5%-14%), selenium powder (Se, 200 mesh, 99.999%), trioctylphosphine (TOP), stearic acid (HSt, 90+), indium acetate (In(Ac)₃, 99.99%), calcium acetate hydrate (Ca(Ac)₂·xH₂O, 99%), nickel acetate tetrahydrate (Mn(Ac)₂·4H₂O, Mn 22%), and manganese acetate tetrahydrate (Ni(Ac)₂·4H₂O, 98+%) were purchased from Alfa Aesar. Sulfur powder (S, 99.98%), dodecanoic acid (HLa, ≥99%), oleic acid (HOl, 90%), and silver acetate (AgAc, 99%) were obtained from Sigma-Aldrich. Anhydrous copper(II) acetate (Cu(Ac)₂, 99.99%), oleylamine (98%), and octylamine (99%) were purchased from Aladdin. Lead acetate trihydrate (Pb(Ac)₂·3H₂O, 99.999%) and tributylphosphine (TBP) were purchased from Acros. Squalene was purchased from TCI. Octylphosphonic acid was purchased from Energy Chemical, USA. All organic solvents were purchased from Sinopharm Chemical Reagent, China. All the above chemicals were used directly without any purification.

### Preparation of Anion Precursors:

Selenium powder (0.2367 g, 3.00 mmol) was dispersed in ODE (10 mL) by sonication for 5 min to prepare a 0.3 mol·L⁻¹ Se suspension.

Selenium powder (0.3156 g, 4.00 mmol) was dispersed in ODE (10 mL) by sonication for 5 min to prepare a 0.4 mol·L⁻¹ Se suspension.

Selenium powder (0.1578 g, 2.00 mmol) was dissolved in TOP (2 mL) by sonication for 5 min to prepare a 1.00 mol·L⁻¹ TOP-Se solution.

S powder (0.0641 g, 2.00 mmol) was dissolved in TOP (2 mL) by sonication for 5 min to prepare a 1.00 mol·L⁻¹ TOP-S solution.

### Preparation of Metal Ion Precursors:

In a typical preparation of a Cu(Ac)₂ solution, Cu(Ac)₂ powder (0.0182 g, 0.1 mmol) was dissolved in TOP (1.0 mL) and HOl (1.0 mL) by sonication until a clear solution was formed, so as to prepare a 0.05 mol·L⁻¹ Cu(Ac)₂ solution. ODE was added to adjust the concentration of the Cu(Ac)₂ solution for subsequent use. Preparation of other metal cation precursors was similar to that of the Cu(Ac)₂ solution.

### Synthesis of Zinc-Blende CdSenanocrystals

A typical synthesis of zinc-blende CdSenanocrystals (the first exciton absorption peak of UV-vis spectrum being at 550 nm and the average diameter being 3.0 nm) was as follows: CdO (0.1024 g, 0.8 mmol), HSt (0.9103 g, 3.2 mmol), and ODE (24.0 mL) were loaded into a 50 mL three-neck flask. The mixture was stirred, bubbled with argon for 10 min, and then heated to 280° C. to obtain a colorless solution. The temperature was lowered to 250° C., and 1 mL of the Se suspension (0.4 mo·L⁻¹) was rapidly injected into the hot solution, thereby lowering the temperature to 220° C. The reaction temperature was maintained at 250° C. for further growth. After 8 min of growth, Sesuspension (0.4 mol·L⁻¹) was added dropwise into the reaction flask at a rate of 1.0 mL/h. Needle-tip aliquots were taken out and dissolved in toluene for UV-vis spectroscopy to monitor the reaction progress. The addition of the Sesuspension was repeated until the desired size of CdSenanocrystals was reached. When the desired size of CdSe was reached, the reaction mixture was cooled to room temperature.

Atypical synthesis of larger CdSenanocrystals (the first exciton absorption peak of UV-vis spectrum being at 630 nm) was as follows: CdO (0.1024 g, 0.8 mmol), HSt (1.2802 g, 4.5 mmol), HLa (1.3326 g, 6.7 mmol), and ODE (10.0 mL) were loaded into a 50 mL three-neck flask. The mixture was stirred, bubbled with argon for 10 min, and then heated to 280° C. to obtain a colorless solution. The temperature was lowered to 250° C., and 0.3 μmol of the purified CdSe (the first exciton absorption peak position of UV-vis spectrum being at 550 nm) was injected into the solution. When the temperature reached 250° C., a Cd(Ol)₂ solution (0.15 mol·L⁻¹) was added dropwise into the reaction flask at a rate of 1.26 mL/h using a syringe pump. At the same time, Sesuspension (0.3 mol·L⁻¹) was added dropwise into the reaction flask at a rate of 0.53 mL/h. Needle-tip aliquots were taken out and dissolved in toluene for UV-vis spectroscopy to monitor the reaction progress. The addition of the Sesuspension and Cd(Ol)₂ solution was repeated until the desired size of CdSenanocrystals was reached. When the desired size of CdSe was reached, the reaction mixture was allowed to cool to room temperature in the air.

### Purification of Zinc-Blende CdSenanocrystals

The reaction mixture (4 mL) was loaded into a 20 mL vial and kept at 50° C. as a clear solution. 10 mL of acetone and 1 mL of methanol were added into the vial. The mixture was vortexed and centrifuged at 4000 rpm, and then the supernatant was removed. The precipitate was dissolved in about 2 mL of toluene. 4 mL of methanol was added at room temperature and the mixture was heated at 60° C. with magnetic stirring for 50 min. After centrifugation at 4000 rpm, the supernatant was removed. The precipitation process was repeated twice. The purified CdSenanocrystals were dissolved in ODE.

### Example 1

### Synthesis of Alloyed CdSe/ZnSe Core-Shell Nanocrystals

In a typical synthesis of green-emitting CdSe/ZnSenanocrystals, ODE (4.5 mL), TOP (0.5 mL), ZnSt₂ (0.1581 g, 0.25 mmol), and HLa (0.2004 g, 1.00 mmol) were added into a three-neck flask. The mixture was stirred, bubbled with argon for 10 min, and then heated to 300° C., followed by a rapid injection of a mixed solution of CdSe (the first exciton absorption peak of UV-vis spectrum being at 550 nm) seed crystals (8×10⁻⁵ mmol, dissolved in 0.4 mL of ODE) and TOP-Se (0.25 mL, 1.00 mol·L¹). The reaction temperature was maintained at 300° C. Needle-tip aliquots were taken out and dissolved in toluene for UV-vis spectroscopy and PL measurements to monitor the reaction.

The reaction typically lasted for 1 h, but the reaction time might be adjusted as needed.

### Copper-Catalyzed Synthesis of Uniform Alloy CdₓZn₁₋ₓSe Nanocrystals

To synthesize blue-emitting alloy CdₓZn₁₋ₓSe (0<x<1) nanocrystals, after 1-hour reaction for the formation of green-emitting slightly alloyed CdSe/ZnSe core-shell nanocrystals, 0.4 mL of a Cu(Ol)₂ solution (0.2 mmol/L) was injected into the reaction flask, at which time [Cu]:[nanocrystal]=1:1 (“[nanocrystal]” represents the molar concentration of nanocrystals, and so on below). The reaction temperature was maintained at 300° C. Needle-tip aliquots were taken out and dissolved in toluene for UV-vis spectroscopy and PL measurements to monitor the reaction. The reaction typically lasted for 2 h, but the reaction time might be adjusted as needed.

### Synthesis of Uniform Alloy CdₓZn₁₋ₓSe/ZnSe/ZnS Core-Shell Nanocrystals (Blue-Emitting)

After 2-hour reaction for the formation of CdₓZn₁₋ₓSe uniform alloy nanocrystals, the reaction mixture was cooled to room temperature. ZnSt₂ (0.3794 g, 0.60 mmol) and HLa (0.4810 g, 2.40 mmol) were added into the three-neck flask. The mixture was stirred, bubbled with argon for 10 min, and then heated to 290° C. After stabilization at 290° C. for 10 min, TOP-Se (0.3 mL, 1.00 mol·L⁻¹) was added dropwise in 25 min. After the formation of the CdₓZn₁₋ₓSe/ZnSe core-shell nanocrystals, 0.2 mL of a TOP-S(1.00 mol·L⁻¹) solution was added dropwise in 20 min to synthesize CdₓZn₁₋ₓSe/ZnSe/ZnS core-shell nanocrystals.

### Example 2

The difference between this example and Example 3 below lies in that the alloying temperature was 300° C. for the first 30 min, then the reaction was continued for another 90 min with the temperature raised and maintained at 330° C., and the ODE was replaced by squalene.

### Example 3

The difference between this example and Example 1 lies in that the synthesis targeted alloyed CdSe/ZnSe core-shell nanocrystals (red-emitting), in which larger-size CdSe (the first exciton absorption peak of UV-vis spectrum being at 630 nm) seed crystals were used, and the 0.5 mmolHLa was changed to 0.5 mmolHSt, while other conditions remained unchanged.

The difference between this example and Example 1 also lies in that in the copper-catalyzed synthesis (4-hour reaction) of uniform alloy CdₓZn₁₋ₓSe nanocrystals, the green-emitting CdSe/ZnSenanocrystals were replaced by the alloyed CdSe/ZnSe core-shell nanocrystals (red-emitting) described above, while other conditions remained unchanged. Finally, uniform alloy CdₓZn₁₋ₓSe/ZnSe/ZnS core-shell nanocrystals (green-emitting) were prepared.

### Example 4

The difference between this example and Example 1 lies in the concentration of copper ions, because 1.2 mL of a Cu(Ol)₂ solution (0.2 mmol/L) was injected in this example, at which time [Cu]:[nanocrystal] (i.e., the molar concentration ratio)=3:1.

### Example 5

The difference between this example and Example 1 lies in the concentration of copper ions, because 2.4 mL of a Cu(Ol)₂ solution (0.2 mmol/L) was injected in this example, at which time [Cu]:[nanocrystal]=6:1.

### Example 6

The difference between this example and Example 1 lies in the concentration of copper ions, because 4 mL of a Cu(Ol)₂ solution (0.2 mmol/L) was injected in this example, at which time [Cu]:[nanocrystal]=10:1.

### Purification of CdSe/ZnSe Core-Shell Nanocrystals, CdₓZn₁₋ₓSe, CdₓZn₁₋ₓSe/ZnSe Core-Shell Nanocrystals, and CdₓZn₁₋ₓSe/ZnSe/ZnS Core-Shell Nanocrystals

The reaction mixture (5 mL) was loaded into a 20 mL vial. 10 mL of acetone was added into the vial. The mixture was vortexed and centrifuged at 4000 rpm, and then the supernatant was removed. The precipitate was dissolved in about 2 mL of hexane. 5 mL of acetone and 0.5 mL of methanol were added at room temperature. After centrifugation at 4000 rpm, the supernatant was removed. This process was repeated twice. The purified nanocrystals were dissolved in organic solvents for different applications.

### Comparative Example

### Synthesis of Alloyed CdSe/ZnSe Core-Shell Nanocrystals

In a typical synthesis of green-emitting CdSe/ZnSenanocrystals, ODE (4.5 mL), TOP (0.5 mL), ZnSt₂ (0.1581 g, 0.25 mmol), and HLa (0.2004 g, 1.00 mmol) were added into a three-neck flask. The mixture was stirred, bubbled with argon for 10 min, and then heated to 300° C., followed by a rapid injection of a mixed solution of CdSe (the first exciton absorption peak of UV-vis spectrum being at 550 nm) seed crystals (8×10⁻⁵ mmol, dissolved in 0.4 mL of ODE) and TOP-Se (0.25 mL, 1.00 mol·L¹). The reaction temperature was maintained at 300° C. Needle-tip aliquots were taken out and dissolved in toluene for UV-vis spectroscopy and PL measurements to monitor the reaction. The reaction typically lasted for 1 h.

It was found through the experiments that in the comparative example, due to no participation of copper ions, the alloying was not uniform and only partial alloying occurred.

### Analytical Method

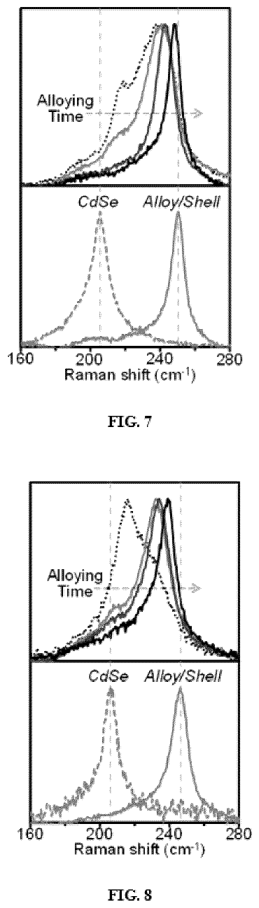

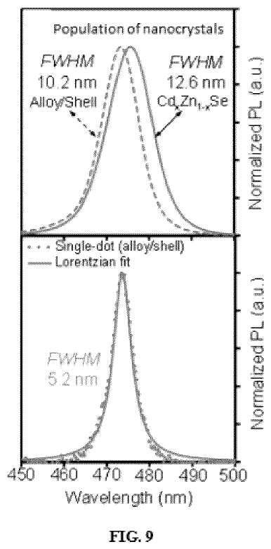

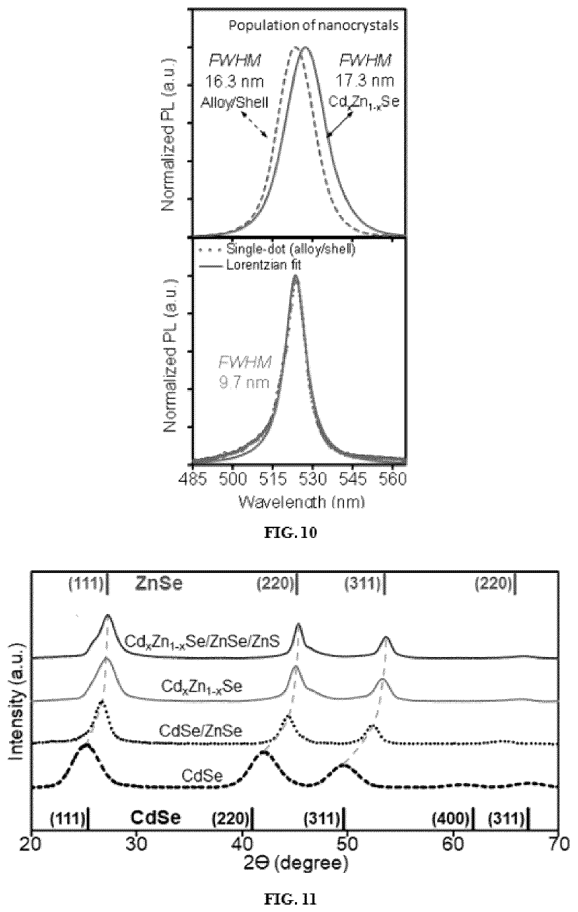

Etching of CdₓZn₁₋ₓSe alloy and core-shell nanocrystals: The purified alloy CdₓZn₁₋ₓSe (or core-shell) nanocrystals were redispersed in 4 mL of toluene for etching. For a typical etching process, 0.6 mmol of octylphosphonic acid, 0.6 mL of tributylphosphine, 10 μL of octylamine, and a solution (1 mL) of the purified alloy nanocrystals were added into a three-neck flask containing 7 mL of toluene. The mixture was heated to 70° C. 1 μL of an aqueous hydrochloric acid solution (1.2 mol/L) was added into the toluene solution. The etching process was monitored using absorption spectroscopy, which typically lasted for 5-10 min. The addition of the hydrochloric acid solution was repeated, if desired. When the alloy nanocrystals were etched to the designated size, 16 mL of methanol was added to precipitate the nanocrystals. The precipitate was redissolved in 2 mL of hexane. 5 mL of acetone and 0.5 mL of methanol were added at room temperature. After centrifugation at 4000 rpm, the supernatant was removed. The precipitation was repeated three to five times until the nanocrystals became hardly soluble in hexane. 700 μL of aqua regia was added into the separated precipitate to digest the nanocrystals. Distilled water was added to adjust the concentration of the digested solution for atomic absorption spectrometry measurements. Etching results of the alloy nanocrystals of Example 1 are shown in FIG. 6. The molar percentages of zinc and cadmium in the free state after etching remained substantially unchanged, demonstrating that the composition of the alloy nanocrystals was distributed uniformly.

Optical measurements of population of nanocrystals: UV-vis spectra were obtained on an Analytik Jena S600 UV-vis spectrophotometer. Photoluminescence spectra were recorded on an Edinburgh Instrument FLS920. Atomic absorption spectra were collected on a thermos M6 atomic absorption spectrometer.

Raman measurements: Raman measurements were conducted using a homemade confocal Raman system. All samples were purified prior to measurements. All samples were dissolved in cyclohexane and loaded into a quartz cuvette. The excitation source was a diode-pumped solid-state laser (Cobalt, 04-01-473) at 473 nm. The Raman scattering light was collected by a Princeton Instrument SP2750 monochrometer and a Pylon 400BRX CCD camera.

TEM and X-ray powder diffraction (XRD) measurements: TEM images were taken on a Hitachi 7700 transmission electron microscope at an acceleration voltage of 80 kV using copper grids (400 mesh) coated with a pure carbon support film. XRD measurements were conducted on a Rigaku Ultimate IV X-ray diffractometer operated at 40 kV/30 mA with Cu kα line (λ=1.5418 Å). Nanocrystal powder samples were placed onto glass substrates after purification by a standard precipitation procedure using n-hexane as a solvent, and acetone and methanol as precipitants. FIG. 11 shows that the nanocrystals at each stage have a zinc-blende structure.

Single nanocrystal optical measurements: The purified CdₓZn₁₋ₓSe/ZnSe/ZnS core/shell/shell nanocrystals were dispersed into a toluene solution containing 3 wt % PMMA, followed by spin-coating onto a clean quartz cover glass. The final density of the nanocrystals on the cover glass was 0.1-0.01/μm². Optical properties were tested on an epi-fluorescence inverted microscopy system (Olympus IX 83) incorporated with a spectrometer (Andor 193i, equipped with 300 L/mm grating and iXon Ultra 897 EMCCD). An excitation beam from 395 nm picosecond laser (PiLas-PiLO37X, with a repetition rate of 1 MHz) was focused onto the object plane with an objective lens (oil-immersed, 60×), and emission from the nanocrystals was collected with the same objective lens. Laser signal was blocked by a long pass filter with a cutoff wavelength of 400 nm and then projected onto the entrance slit of the spectrometer. Spectral signal was acquired using the “kinetic mode” of EMCCD with 1 s exposure per frame. The data shown in the lower panels of FIG. 9 and FIG. 10 are the average results from 20 frames.

The populations of alloy nanocrystals, populations of core-shell nanocrystals, and single core-shell nanocrystals obtained in some of the examples, as well as the population of partially alloyed nanocrystals obtained in Comparative Example 1 were tested, and the optical test results are shown in Table 1 below.

TABLE 1

| | Fluorescence | | Single-nano | | | |
|---|---|---|---|---|---|---|
| | emission peak | PL | crystal PL | Raman | Raman | Quantum |
| | wavelength | FWHM | FWHM | shift | FWHM | efficiency |
| Nanocrystal | (nm) | (nm) | (nm) | (cm⁻¹) | (cm⁻¹) | (%) |
| Alloy nanocrystals from | 474 | 12.6 | / | 248.4 | 9.6 | 51 |
| Example 1 | | | | | | |
| Alloy core-shell | 473 | 10.2 | 5.2 | 250.6 | 9.6 | 65 |
| nanocrystals from | | | | | | |
| Example 1 | | | | | | |
| Alloy nanocrystals from | 528 | 17.3 | / | 239.6 | 13.6 | 56 |
| Example 2 | | | | | | |
| Alloy core-shell | 525 | 16.3 | 9.7 | 246.2 | 12.4 | 67 |
| nanocrystals from | | | | | | |
| Example 2 | | | | | | |
| Alloy nanocrystals from | 531.2 | 17.3 | / | / | / | / |
| Example 3 | | | | | | |
| Alloy nanocrystals from | 464 | 13.7 | / | / | / | / |
| Example 4 | | | | | | |
| Alloy nanocrystals from | 46. | 12.8 | / | / | / | / |
| Example 5 | | | | | | |
| Alloy nanocrystals from | 461 | 12.9 | / | / | / | / |
| Example 6 | | | | | | |
| Nanocrystals from | 550 | 21 | / | 230 | 36 | / |
| Comparative Example | | | | | | |

The composition of the populations of alloy nanocrystals obtained in some of the examples and the comparative example was analyzed using atomic absorption spectroscopy (AAS), and the test results are shown on the right side of Table 2. The results on the left side of Table 2 were calculated based on the amount of each precursor fed during the experimental process.

TABLE 2

| Ratio of cations calculated based on reaction feeds | | | | Ratio of cations measured by AAS | | | |
|---|---|---|---|---|---|---|---|
| [Cu]/ | Cd | Zn | Cu | [Cu]/ | Cd | Zn | Cu |
| [nanocrystal] | mol % | mol % | mol % | [nanocrystal] | mol % | mol % | mol % |
| 0 (Comparative | 7.64 | 92.36 | 0.00 | 0.00 | 11.02 | 88.98 | 0.00 |
| Example) | | | | | | | |
| 1 (Example 1) | 7.64 | 92.34 | 0.03 | 0.39 | 9.11 | 90.88 | 0.01 |
| 1 (Example 2) | 32.16 | 67.82 | 0.02 | / | / | / | / |
| 3 (Example 4) | 7.63 | 92.28 | 0.09 | 0.88 | 9.33 | 90.64 | 0.03 |
| 6 (Example 5) | 7.62 | 92.20 | 0.18 | 1.33 | 9.43 | 90.53 | 0.04 |
| 10 (Example 6) | 7.61 | 92.09 | 0.29 | 2.23 | 9.39 | 90.54 | 0.07 |

As can be seen from Table 2, considering that the nanocrystals were purified to the extent that there was almost no zinc carboxylate ligand on the surface of the nanocrystals prior to the AAS test, the results obtained in both ways were actually within the allowable error range, and the results of zinc-cadmium content were substantially identical. The reason for the difference in [Cu]/[nanocrystal] is that copper as a catalyst did not enter all of the nanocrystals, so the copper was mainly free in the solution of the reaction system and thus there was no emission characteristic of copper.

The foregoing is merely illustrative of the preferred embodiments of the present disclosure and is not intended to limit the present disclosure, and various modifications and changes can be made to the present disclosure by those skilled in the art. Any modification, equivalent, improvement and the like made without departing from the spirit and principle of the present disclosure shall fall within the protection scope of the present disclosure.

What is claimed is:

1. (canceled)

2. (canceled)

3. (canceled)

4. (canceled)

5. (canceled)

6. (canceled)

7. (canceled)

8. (canceled)

9. (canceled)

10. (canceled)

11. (canceled)

12. A population of core-shell nanocrystals, wherein the population of core-shell nanocrystals comprises at least one core-shell nanocrystal, the core-shell nanocrystal comprising one alloy nanocrystal in population of alloy nanocrystals and further comprising a II-VI shell layer that coats the alloy nanocrystal the population of alloy nanocrystals comprising a plurality of alloy nanocrystals, wherein each of the alloy nanocrystals comprises a first group II element, a second group II element, and a first group VI element, the population of alloy nanocrystals has a Raman peak with a full-width-at-half-maximum of less than or equal to 15 cm⁻¹, and the alloy nanocrystals have an average size greater than a Bohr diameter of an exciton of a corresponding bulk alloy compound.

13. The population of core-shell nanocrystals according to claim 12, wherein the II-VI shell layer is ZnS, ZnSe, or a combination thereof.

14. The population of core-shell nanocrystals according to claim 12, wherein the II-VI shell layer comprises a ZnSe shell layer and a ZnS shell layer, the ZnSe shell layer being equivalent to 5-6 monolayers and the ZnS shell layer being equivalent to 1-2 monolayers.

15. The population of core-shell nanocrystals according to claim 12, wherein the population of core-shell nanocrystals has a photoluminescence emission wavelength of 455-475 nm and a fluorescence full-width-at-half-maximum of less than or equal to 11 nm.

16. The population of core-shell nanocrystals according to claim 12, wherein the population of core-shell nanocrystals has a photoluminescence emission wavelength of 520-535 nm and a fluorescence full-width-at-half-maximum of less than or equal to 17 nm.

17. The population of core-shell nanocrystals according to claim 12, wherein the population of core-shell nanocrystals has a quantum efficiency of greater than or equal to 60%.

18. The population of core-shell nanocrystals according to claim 12, wherein the population of core-shell nanocrystals has a Raman peak with a Raman shift of 239-248 cm⁻¹.

19. The population of core-shell nanocrystals according to claim 12, wherein the population of core-shell nanocrystals has a Raman peal with a full-width-at-half-maximum of less than or equal to 12 cm⁻¹ or less than or equal to 10 cm⁻¹.

20. (canceled)

21. An electronic device, comprising the population of alloy nanocrystals according to the population of core-shell nanocrystals according to claim 12.

22. (canceled)

23. (canceled)

24. (canceled)

25. (canceled)

26. (canceled)

27. (canceled)

28. (canceled)

29. (canceled)

30. (canceled)

31. (canceled)

32. (canceled)

33. (canceled)

34. (canceled)

35. (canceled)

36. (canceled)

37. A synthesis method for a population of core-shell nanocrystals, comprising:
S1, preparing a dispersion containing first II-VI nanocrystal cores;
S2, preparing a mixture containing a second group II element precursor, a second group VI element precursor, a free ligand, and a solvent in a reaction container, heating the mixture to a first temperature, adding the dispersion into the reaction container, and epitaxially growing a plurality of first II-VI-second II-VI core-shell nanocrystals, wherein a second group III element in the second group II element precursor is different from a first group II element in the first II-VI nanocrystal cores, and an average size of the first II-VI/second II-VI core-shell nanocrystals is controlled to be greater than a Bohr diameter of an exciton of a group II-VI compound containing the same corresponding elements; and
S3, adding metal ions as a catalyst into the reaction container and conducting, at a second temperature, a conversion of the first II-VI/second II-VI core-shell nanocrystals into alloy nanocrystals to obtain a population of alloy nanocrystals comprising a plurality of the alloy nanocrystals;
S4, epitaxially growing a first shell layer on a surface of the alloy nanocrystal and epitaxially growing a second shell layer on a surface of the first shell layer;
the second group II element precursor and the second group VI element precursor are in a molar ratio of 10:1 to 1:2;
the free ligand comprises a fatty acid;
the fatty acid and the second group II element precursor are in a molar ratio of 1:1 to 4:1;
shell layers in the first II-VI/second II-VI core-shell nanocrystals have a thickness of greater than 4 monolayers or greater than 2.5 mm;
the conversion is conducted at a reaction temperature of 300-330° C.;
the metal ions and the first II-VI/second II-VI core-shell nanocrystals are in a molar concentration ratio of 1:1 to 1:10;
the second group II element precursor comprises a fatty acid salt of a second group II element, and no fatty amine is present in the reactions of both S2 and S3.

38. The population of alloy nanocrystals according to claim 12, wherein the population of alloy nanocrystals has a fluorescence full-width-at-half-maximum of less than or equal to 18 nm, and the alloy nanocrystals have a zinc-blende structure.

39. The population of alloy nanocrystals according to claim 12, wherein the alloy nanocrystals are CdZnSe.

40. The population of alloy nanocrystals according to claim 39, wherein the alloy nanocrystals have a cadmium-to-zinc molar ratio of 7:93 to 33:67.

41. The population of alloy nanocrystals according to claim 12, wherein the alloy nanocrystals are free of light emission by copper element.

42. The population of alloy nanocrystals according to claim 12, wherein a ligand of the alloy nanocrystals comprises trialkylphosphine and carboxylate.

43. The synthesis method for a population of core-shell nanocrystals according to claim 37, wherein the second group II element precursor and the second group VI element precursor are in a molar ratio of 10:1 to 1:2.

44. The synthesis method for a population of core-shell nanocrystals according to claim 37, wherein the free ligand comprises a fatty acid.

45. The synthesis method for a population of core-shell nanocrystals according to claim 44, wherein the fatty acid and the second group II element precursor are in a molar ratio of 1:1 to 4:1.

46. The synthesis method for a population of core-shell nanocrystals according to claim 37, wherein shell layers in the first II-VI/second II-VI core-shell nanocrystals have a thickness of greater than 4 monolayers or greater than 2.5 nm.

47. The synthesis method for a population of core-shell nanocrystals according to claim 37, wherein the conversion is conducted at a reaction temperature of 300-330° C.

48. The synthesis method for a population of core-shell nanocrystals according to claim 37, wherein the metal ions and the first II-VI/second II-VI core-shell nanocrystals are in a molar concentration ratio of 1:1 to 1:10.

49. The synthesis method for a population of core-shell nanocrystals according to claim 37, wherein the second group II element precursor comprises a fatty acid salt of a second group II element, and no fatty amine is present in the reactions of both S2 and S3.
